(19) United States
(12) Patent Application Publication
(10) Pub. No.: US 2023/0317744 A1
(43) Pub. Date: Oct. 5, 2023

(54) PHOTODIODE AND FABRICATION METHOD OF A PHOTODIODE

(71) Applicant: STMicroelectronics (Crolles 2) SAS, Crolles (FR)

(72) Inventors: Boris RODRIGUES GONCALVES, THEYS (FR); Pascal FONTENEAU, THEYS (FR)

(73) Assignee: STMicroelectronics (Crolles 2) SAS, Crolles (FR)

(21) Appl. No.: 18/127,286

(22) Filed: Mar. 28, 2023

(30) Foreign Application Priority Data
Apr. 1, 2022 (FR) 2202997

(51) Int. Cl. H01L 27/146; G01S 7/481; G01S 17/89

(52) U.S. Cl. CPC H01L 27/1461; H01L 27/14649; H01L 27/1463; H01L 27/14689; G01S 7/4816; G01S 17/89

(57) ABSTRACT

A photodiode is formed in a semiconductor substrate having a first surface and a second surface. The semiconductor substrate includes a first N-type semiconductor region formed by epitaxial growth and a second N-type semiconductor region (that is more heavily doped than the first region) extending into the first N-type semiconductor region from the first surface. The dopant concentration of the first N-type semiconductor region gradually increases between the second surface and the first surface of the semiconductor substrate. An implanted heavily P-type doped region is formed in the second N-type semiconductor region at the first surface.

### PRIORITY CLAIM

This application claims the priority benefit of French Application for Patent No. 2202997, filed on Apr. 1, 2022, the content of which is hereby incorporated by reference in its entirety to the maximum extent allowable by law.

### TECHNICAL FIELD

The present disclosure generally relates to electronic components and more precisely photodiodes.

The present disclosure also relates to electronic devices, such as image sensors comprising photodiodes.

### BACKGROUND

A photodiode is a semiconductor component having a PN junction and having the ability to detect a light radiation and to transform it into an electric signal. More precisely, the light forms electrons in an active area of the photodiode. These electrons then have to be recovered by an electronic circuit.

An image sensor is an electronic device that may comprise a plurality of photodiodes, the photodiodes enabling the image sensor to obtain an image of a scene at a given time. The image is generally formed of a pixel array, the information of each pixel being obtained by one or a plurality of photodiodes.

In a time-of-flight (TOF) detection pixel, the pixel receives the light emitted by a light source and then reflected by a point of the scene conjugated with this pixel. The measurement of the time of flight, that is, the time taken by light to travel from the light source to the point of the scene having the pixel conjugated therewith, and from this point to the pixel, enables to calculate the distance separating the pixel from this point.

In a TOF image sensor with photodiodes, typically an indirect TOF sensor, the electrons formed at a given time, during the capture of a scene, are generally transferred into a memory, and the quantity of electrons is then read by an electronic circuit to obtain information relative to the scene. For the information relative to the scene to be accurate and to correspond to a given time, it is preferable for the electrons to displace rapidly towards the memory.

Indeed, for an indirect TOF sensor, for example, to form 3D images, the accuracy of the distance measurement is linked to the pixel sampling efficiency, that can be defined by a parameter referred to in the art as “demodulation contrast” (DMC) and to the sensitivity to background light. In other words, the measurement accuracy is linked to the rapidity of the photodiodes of the pixels and may be measured by the DMC. Further, the lower the displacement time, or transfer time, of electrons in a photodiode, the higher the demodulation contrast may be, and conversely.

There exists a need to decrease the time of transfer of electrons in a photodiode, for example, to increase the demodulation contrast of a pixel comprising such a photodiode.

### SUMMARY

An embodiment overcomes all or part of the disadvantages of known photodiodes.

An embodiment provides a photodiode formed in a semiconductor substrate having a first surface and a second surface, the substrate comprising a first N-type semiconductor region formed by epitaxial growth and a second N-type semiconductor region more heavily doped than the first N-type semiconductor region, said second N-type semiconductor region extending from the first surface of the substrate down to a first depth in the first N-type semiconductor region; the dopant concentration in the first N-type semiconductor region gradually increasing between the second surface and the first surface of the substrate.

According to an embodiment, the substrate further comprises a P-type semiconductor region between the first N-type semiconductor region and the second surface of the substrate.

According to an embodiment, the photodiode further comprises a heavily P-type doped semiconductor region, on the second N-type semiconductor region at the level of the first surface of the substrate.

According to embodiments: the height of the first N-type semiconductor region is in the range from 4.5 μm to 10 μm, for example from 4.5 to 7.5 μm; and/or the depth of the second N-type semiconductor region is in the range from 1 μm to 2 μm; and/or the height of the P-type semiconductor region is in the range from 0.5 μm to 3 μm, for example, from 0.5 to 1.5 μm .

An embodiment provides a method of manufacturing a photodiode in a semiconductor substrate having a first surface and a second surface, the method comprising: providing a first substrate; forming, by epitaxial growth on the first substrate, a first N-type semiconductor region, comprising a gradual increase of N-type dopant concentration during said epitaxial growth, so that the first formed N-type semiconductor region comprises a first surface most distant from the first substrate, more heavily N-type doped than a second surface closest to the first substrate; and forming a second N-type semiconductor region more heavily doped than the first N-type semiconductor region, said second N-type semiconductor region being formed from the first surface of the first N-type semiconductor region, at the level of the first surface of the substrate, down to a first depth in said first N-type semiconductor region.

According to embodiments that may apply to a photodiode or to a photodiode manufacturing method: the dopant concentration of the first N-type semiconductor region increases by a ratio in the range from 2 to 100, for example from 2 to 10, or even from 2 to 4; and/or the dopant concentration of the second N-type semiconductor region is of a few 10¹⁷ at./cm^{3;} and/or the second N-type region is formed by ion implantation.

According to an embodiment, the first substrate comprises a P-type semiconductor region, and forming by epitaxial growth of the first N-type semiconductor region is performed from the P-type semiconductor region.

According to an embodiment, the method comprises, prior to forming the first N-type semiconductor region, the forming a P-type semiconductor region by epitaxial growth from the first substrate, and forming by epitaxial growth of the first N-type semiconductor region is performed from said P-type semiconductor region.

According to embodiments that may apply to a photodiode or to a photodiode manufacturing method: the dopant concentration of the P-type semiconductor region is substantially constant; or the dopant concentration of the P-type semiconductor region gradually decreases between the second surface of the substrate and the first N-type semiconductor region.

According to an embodiment, the method comprises the forming of a heavily P-doped region on the second N-type semiconductor region.

According to embodiments that may apply to a photodiode or to a photodiode manufacturing method: the dopant concentration of the heavily doped P-type region is in the range from a few 10¹⁸ at./cm³ to a few 10¹⁹ at./cm³; and/or the heavily P-doped region is formed by ion implantation; and/or the substrate is made of silicon; and/or insulating trenches are formed across the height of the substrate to insulate the photodiode, said trenches supporting, for example, capacitive deep trench insulations.

An embodiment provides an electronic device comprising at least one photodiode according to an embodiment.

According to an embodiment, the device is a time-of-flight image sensor comprising a plurality of pixels, each pixel comprising the at least one photodiode.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 is a cross-section view showing an example of a photodiode;

FIG. 2 is a cross-section view showing a photodiode according to an embodiment;

FIG. 3 is a cross-section view showing a photodiode according to another embodiment;

FIG. 4 is a cross-section view showing another example of a photodiode;

FIG. 5 illustrates doping profiles of a photodiode according to the mode of FIG. 2;

FIG. 6 illustrates doping profiles of a photodiode according to the mode of FIG. 3 and of a photodiode according to a variant of the photodiode of FIG. 3;

FIGS. 7A to 7F are cross-section views showing steps of a method of manufacturing a photodiode according to an embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the memory areas, the transfer and readout circuits are not detailed, being known by those skilled in the art. Further, a photodiode has been mainly shown, knowing that it may be integrated in an electronic device, for example, in an image sensor pixel, and a pixel may comprise one or a plurality of photodiodes.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings or to a photodiode in a normal position of use.

Unless specified otherwise, the expressions “around”, “approximately”, “substantially” and “in the order of” signify within 10%, and preferably within 5%.

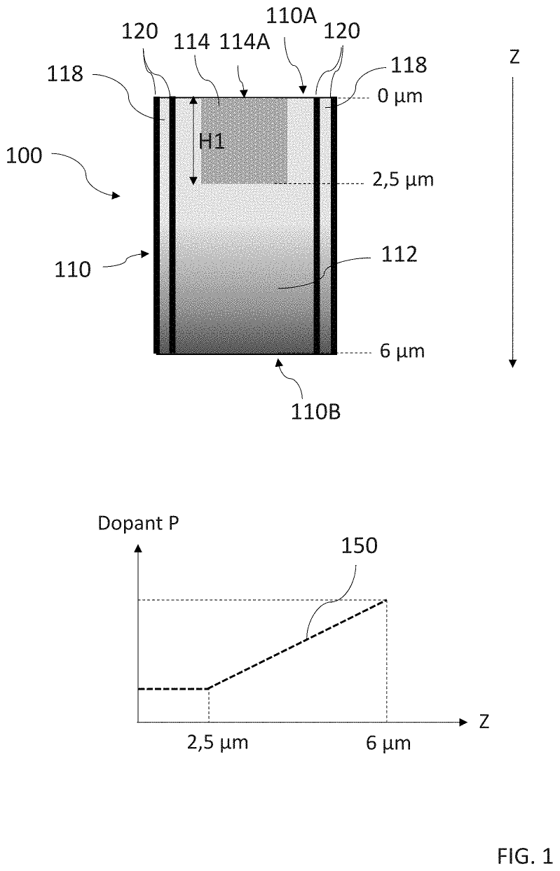

FIG. 1 is a cross-section view illustrating a photodiode 100, for example a photodiode of an image sensor pixel. Photodiode 100 is formed in a semiconductor substrate 110, generally made of silicon. Substrate 110 comprises a P-doped semiconductor region 112 at least partially surrounding an N-doped semiconductor region 114, thus forming a PN junction. N-doped region 114 extends from an upper surface 110A (first surface) of substrate 110 down to a depth H1 in the P-doped region 112. The upper surface 114A of N-doped region 114 is generally covered with a heavily P-doped semiconductor region (not shown), forming another PN junction. Doped semiconductor regions are generally made of silicon.

In the shown example, the height of photodiode 100 is approximately 6 μm and depth H1 is equal to approximately 2.5 μm.

P-doped region 112 is P-type doped with a gradual dopant concentration in the Z direction (i.e., a gradient), corresponding to the height of the photodiode, said concentration increasing away from the N doped region, that is, decreasing between lower surface 100B (second surface) of substrate 110 and the upper surface 110A of said substrate. For example, the P doping of region 112 results from the concentrations of dopant, for example, boron, illustrated by doping profile 150 (“Dopant P”).

Region 114 is, for example, an ion implantation region heavily N-doped, typically in the order of a few 10¹⁷ at/cm³.

As shown, photodiode 100 is delimited on both sides by trenches 120, extending all along the height of said photodiode. Other electronic components, for example, other photodiodes, may be arranged on the other side of the trenches. Two trenches 120 have been shown on each side of photodiode 100, as further explained hereafter, but there may be a single trench on each side.

Trenches 120 comprise an insulating material and, in certain cases, a conductive or semiconductor material. For example, trenches 120 are filled with a conductive or semiconductor element, such as metal or polysilicon, which is insulated from substrate 110 by a layer of insulator. The trenches may thus form capacitive deep trench isolations (CDTI).

In a way not shown, trenches 120 may be biased. Trenches 120 enable, for example, to electrically isolate N-doped region 114 from electromagnetic disturbances or unwanted biasing of substrate 110. According to an example, trenches 120 are negatively biased and substrate 110 is grounded. This enables to obtain a depletion of N-doped region 114 to form a pinned diode.

N-doped region 114 may form an electron collection area. In other words, electrons resulting from a light radiation hitting photodiode 100 may be accumulated in N-doped region 114.

These electrons are generally transferred to a memory area by a transfer circuit that may comprise or consist of a transfer transistor. The memory area may be an electron storage area 118 formed in substrate 110. There has been shown in FIG. 1 with a storage area 118 formed between two trenches 120 and this, on each side of photodiode 100. Other configurations are possible. For example, a memory may be formed in another region of substrate 110, preferably close to the upper surface 110A of substrate 110, and a single trench may be formed on each side of photodiode 100.

The reading of the voltage stored in the memory may be performed by using a readout circuit, for example comprising a follower source transistor having its gate coupled to the memory area (not shown).

A solution to favor the transfer of electrons to the collection area and the storage area (memory), and in particular to increase the speed of electron transfer in the photodiode (charge transfer speed) is the forming of an electric field in the photodiode, which is allowed at least by each PN junction. However, in the example of photodiode shown in FIG. 1, the inventors have observed that the field is much higher at the level of the PN junction than in the P layer, and that the electric isopotential curves are distant from one another, even with a gradual dopant concentration in the Z direction (gradient) as shown and described hereafter.

The inventors provide a photodiode and a method of manufacturing such a photodiode enabling to meet the previously-described improvement needs, and to overcome all or part of the disadvantages of the previously-described photodiodes. In particular, the inventors provide a photodiode and a method of manufacturing such a photodiode enabling to increase the photodiode charge transfer speed, for example to generate an electric field which is the highest and the best distributed possible in the Z direction.

Embodiments of photodiodes will be described hereafter. The described embodiments are non-limiting and various variants will occur to those skilled in the art based on the indications of the present disclosure.

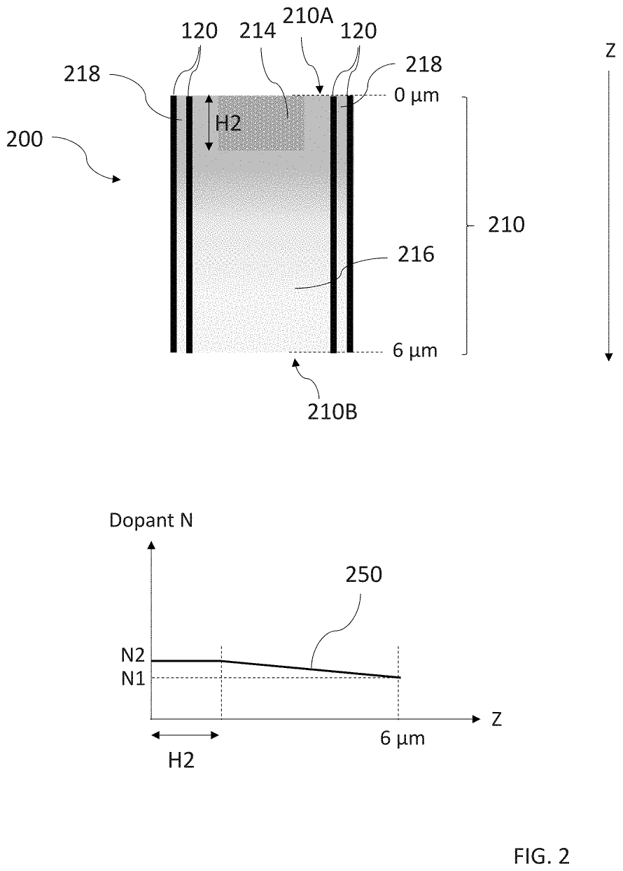

FIG. 2 is a cross-section view showing a photodiode 200 according to an embodiment, for example, a photodiode of an image sensor pixel.

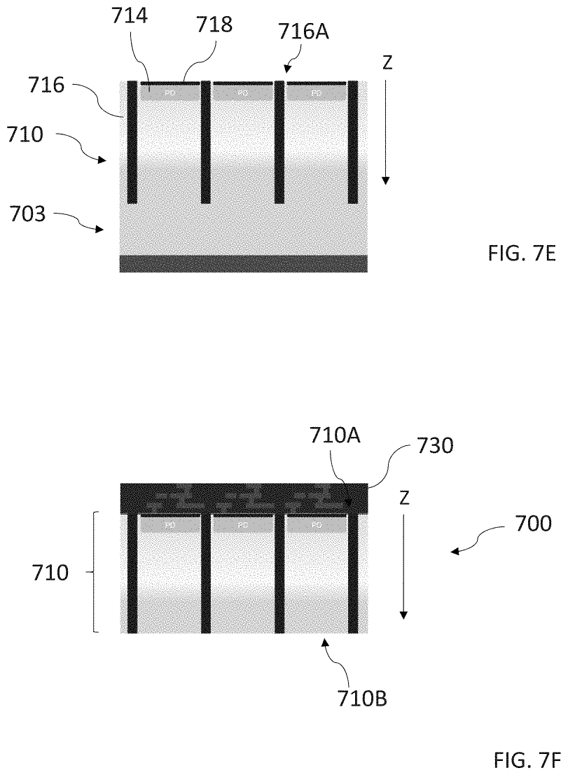

Photodiode 200 is located in a semiconductor substrate 210, generally made of silicon. Substrate 210 comprises a first N-doped semiconductor region 216 at least partially surrounding a second more heavily N-doped semiconductor region 214 which extends from an upper surface 210A (first surface) of substrate 210 down to a depth H2 in first N-doped region 216. The upper surface of the second N-doped region 214 is generally covered with a heavily P-doped semiconductor region (P+ ion implantation region, not illustrated in FIG. 2 but illustrated in FIGS. 7E and 7F), forming a PN junction. Doped semiconductor regions are generally made of silicon.

According to the shown example, the height of the photodiode is approximately 6 μm and depth H2 is equal to approximately 1.5 μm, but these values may be adapted by those skilled in the art, for example, according to the dimensions of the pixel and/or to the desired transfer speed.

First region 216 is N-type doped with a gradual dopant concentration in the Z direction (i.e., a gradient), the concentration decreasing away from N-doped second region 214, that is, increasing between the lower surface 210B (second surface) of the substrate and the upper surface 210A of said substrate.

According to an example, the N-type doping of first region 216 results from the dopant concentrations illustrated by profile 250 (“Dopant N”), having a maximum concentration N2 of dopant (for example, phosphorus) at the closest to second region 214 decreasing to a dopant concentration N1 smaller than N2 at the farthest from second region 214, that is, a concentration gradually increasing between N1 from the lower surface of substrate 210B and N2 at the level of second region 214. N1 may, for example, be in the range from 10¹⁴ to 10¹⁶ at/cm³,or even from 10¹⁴ to 10¹⁵ at/cm³. Ratio N2/N1 may, for example, be in the range from 2 to 100, or even from 2 to 10, or even still from 2 to 4, for example, equal to approximately 2. Those skilled in the art will be capable of adapting the dopant concentration values and the ratios according to the material of the substrate, to the dopant, and according to the desired speed level.

Second region 214 is, for example, a heavily N-doped ion implantation region (N+), typically in the order of a few 10¹⁷ at/cm³. It may form an electron collection area.

Similarly to the photodiode 100 of FIG. 1, photodiode 200 is delimited on both sides by trenches 120, extending all along the height of the photodiode. Trenches 120 may be biased, in particular, trenches 120 may be negatively biased and substrate 210 may be grounded, for example, to obtain a depletion of second N-doped region 214 to form a pinned diode.

Still similarly to what has been described in relation with FIG. 1, the collected electrons may be transferred to a memory area by a transfer circuit that may comprise, or consist of, a transfer transistor. The memory area may be an electron storage area 218 formed in substrate 210. Storage areas 218 are shown between two trenches 120 and this, on each side of photodiode 200. Other configurations are possible. For example, a memory area may be formed in another region of substrate 210, preferably close to the upper surface 210A of substrate 210, and a single trench may be formed on each side of photodiode 200.

The reading of the voltage stored in the memory may be performed by using a readout circuit, for example comprising a follower source transistor having its gate coupled to the memory area (not shown).

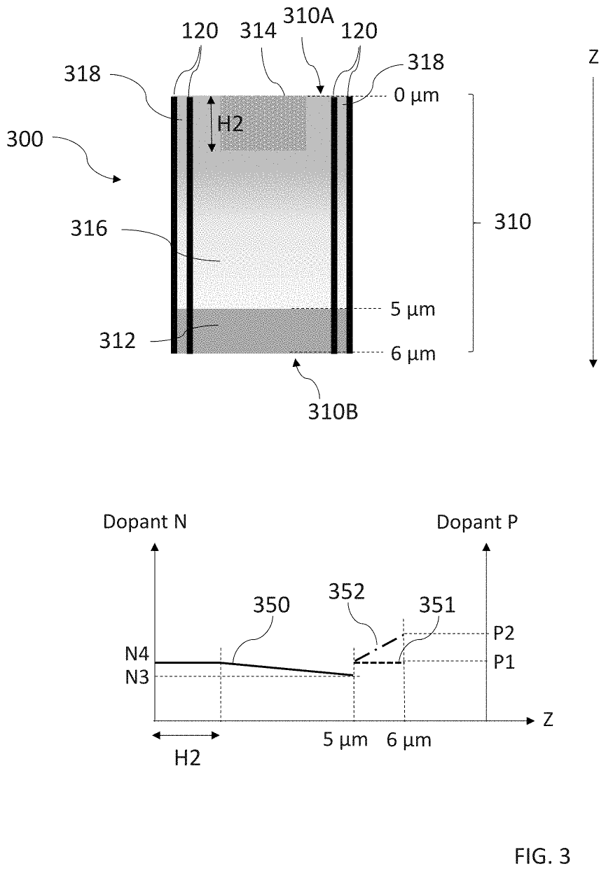

FIG. 3 is a cross-section view showing a photodiode 300 according to another embodiment, which differs from the mode of FIG. 2 mainly in that it comprises a P-doped region 312 under first N-doped region 316. This, for example, enables to form another PN junction, and thus to increase the electric field around this junction, and by incidence in the photodiode.

In the shown example, the height of the photodiode is approximately 6 μμm and P-doped region 312 is located between 5 and 6 μμm (region 312 thus has a thickness in the order of 1 μm), but these values may be adapted by those skilled in the art, for example, according to the pixel dimensions and/or to the desired transfer speed.

According to an example illustrated by doping profile 351 (“Dopant P”), region 312 is P-doped with a substantially constant concentration P1 of dopant, for example, boron. P1 may, for example, be in the range from 10¹⁴ to 10¹⁸ at/cm³, or even from 10¹⁴ to 10¹⁶ at/cm³. Those skilled in the art will be capable of adapting the dopant concentration values according to the material of the substrate, to the dopant, and according to the desired speed level.

According to a variant illustrated by doping profile 352 (“Dopant P”), P-doped region may be doped with a gradual concentration of dopant (gradient), for example, boron, in the Z direction, decreasing towards first N-doped region 316, that is, with a dopant concentration gradually decreasing between the lower surface 310B of substrate 310 and first N-doped region 316, between a concentration P2 and dopant concentration P1. Ratio P2/P1 may, for example, be in the range from 10 to 1,000, or even from 10 to 100. Those skilled in the art will be capable of adapting the dopant concentration values and the ratios according to the material of the substrate, to the dopant, and according to the desired speed level.

First region 316 is N-type doped with a gradual dopant concentration in the Z direction (gradient), said concentration decreasing away from second N-doped region 314 to P-doped region 312. For example, the N-type doping of first region 316 results from the dopant concentrations illustrated by doping profile 350 (“Dopant N”), having a maximum concentration N4 of dopant (for example, phosphorus) at closest to second N-doped region 314 decreasing to a concentration N3 at the level of P-doped region 312. N3 may be within the same ranges as those given for N1, for example may have a value substantially equal to N1, and ratio N4/N3 may be within the same ranges as those given for ratio N2/N1, for example be substantially equal to ratio N2/N1.

Similarly to the photodiode 200 of FIG. 2, photodiode 300 comprises a second semiconductor region 314 more heavily N-doped than first region 316 and which extends from the upper surface 310A of substrate 310 down to a depth H2 in said first region. The upper surface of the second N-doped region 314 is generally covered with a heavily P-doped semiconductor region (P+ ion implantation region), forming a PN junction.

Second region 314 is, for example, a heavily N-doped ion implantation region (N+), typically in the order of a few 10¹⁷ at/cm³. Second region 314 may form an electron collection area.

Similarly to the photodiode 200 of FIG. 2, photodiode 300 is delimited on both sides by trenches 120, extending all along the height of the photodiode, and the collected electrons may be transferred to electron storage areas 318 shown between two trenches 120.

In the embodiments of FIGS. 2 and 3, and more generally in a photodiode according to an embodiment, the first N-doped region 216, 316 and, when it is present, P-doped region 312, are regions preferably obtained by epitaxial growth, since the ion implantation technique generally does not enable, with reasonable implantation energies, to obtain such gradual doping concentrations across such depths.

Further, first N-doped region 216, 316 behaves as an extension of second heavily N-doped region 214, 314 with a doping concentration which decreases away from said second region to a value that may be sufficiently low to resemble a P area, that is, to form a PN pseudo-junction at the bottom of the substrate, without it always being necessary to form a P-type epitaxial region at the bottom of said substrate. This gradual N doping enables to generate a more gradual and stronger electric field in the Z direction (more isopotential lines, closer to one another, in said direction) and thus favor the displacement of charges in the photodiode.

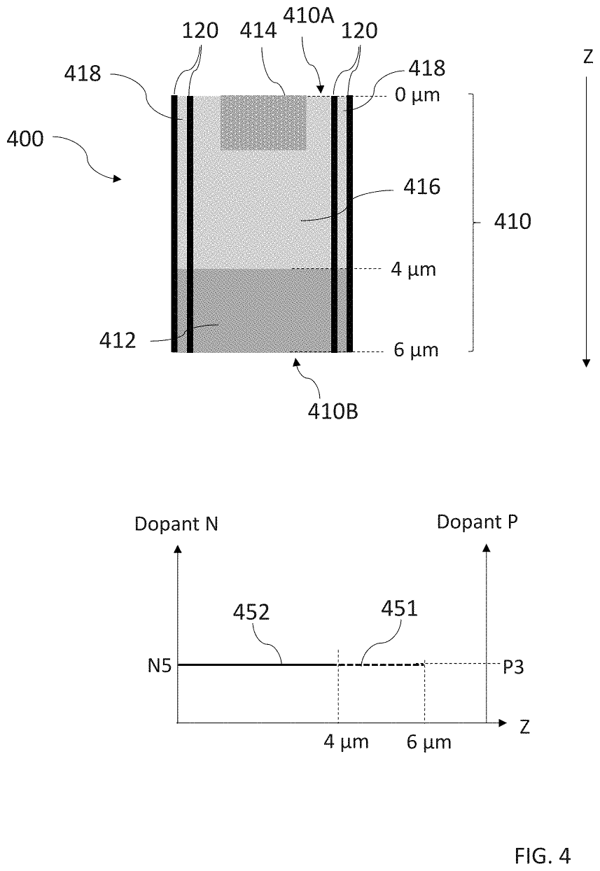

FIG. 4 is a cross-section view showing another example of a photodiode 400, which differs from the photodiode 300 of FIG. 3 mainly in that first region 416 is N doped with a substantially constant and non-gradual concentration.

According to an example illustrated by doping profile 452 (“Dopant N”), region 416 is N doped with a substantially constant concentration N5 of dopant, for example, phosphorus. N5 may be within the same ranges as those given for N1, for example may have a value substantially equal to N1.

According to an example illustrated by doping profile 451 (“Dopant P”), region 412 is P doped with a concentration P3 of dopant, for example, boron. P3 may be substantially equal to N5, or more widely within the same ranges as those given for P1.

Similarly to the photodiode of FIG. 3, according to a variant, the P-doped region may be doped with a gradual dopant concentration in the Z direction (gradient), the dopant concentration gradually decreasing between the lower surface 410B of substrate 410 and first N-doped region 416, for example, similarly to what is described in relation with FIG. 3 (curve 352).

According to the shown example, the height of photodiode 400 is approximately 6 μm and P-doped region 412 is between 4 and 6 μm (region 412 thus has a thickness in the order of 2 μm), but these values may be adapted by those skilled in the art, for example, according to the pixel dimensions and/or to the desired transfer speed.

Table 1 hereafter gathers results compared between photodiodes 100, 200, 300, 400 in terms of demodulation contrast (DMC) at 200 MHz and at 300 MHz, and of charge transfer time. The compared photodiodes have similar dimensions and doping concentrations comparable with one another.

TABLE 1

| | | | | |
|---|---|---|---|---|
| Photodiode | 100 | 200 | 300 | 400 |
| DMC at 200 MHz | 80 | 87 | 92 | 83 |
| DMC at 300 MHz | 67 | 77 | 86 | 74 |
| Transfer time (ns) | 590 | 440 | 315 | 480 |

There appears from these results that the embodiments of photodiodes 200, 300 comprising a gradual N-type epitaxial region clearly improve the demodulation contrast, and advantageously decrease the transfer time, thus improving the operation of the photodiode with respect to photodiode 100. The embodiment of photodiode 300 comprising a gradual N-type epitaxial region on a constant P-type epitaxial region still further improves the operation of the photodiode, that may be further improved with a gradual P-type epitaxial region.

There thus appears from these results that the photodiode 400 described in relation with FIG. 4, where the N-type epitaxial region is not gradual but is formed on a constant P-type epitaxial region, also improve the demodulation contrast, and advantageously decreases the transfer time.

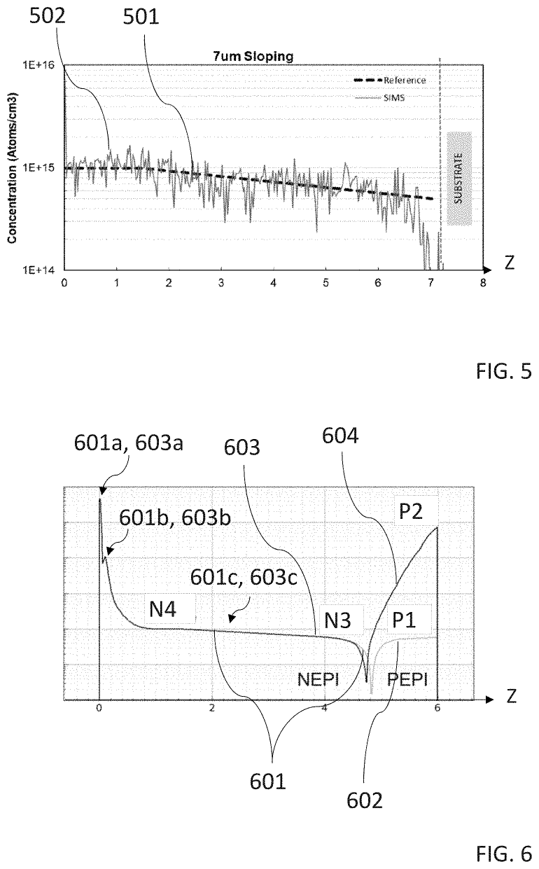

FIG. 5 illustrates N doping profiles 501, 502 in the Z direction of a photodiode 200 according to the embodiment of FIG. 2. The curve 501 in dotted lines corresponds to a theoretical doping profile, which substantially corresponds to the profile given in FIG. 2. Curve 502 in full line corresponds to the real doping profile of the same photodiode measured by secondary ion mass spectrometry (SIMS), which exhibits variations on either side of the theoretical profile.

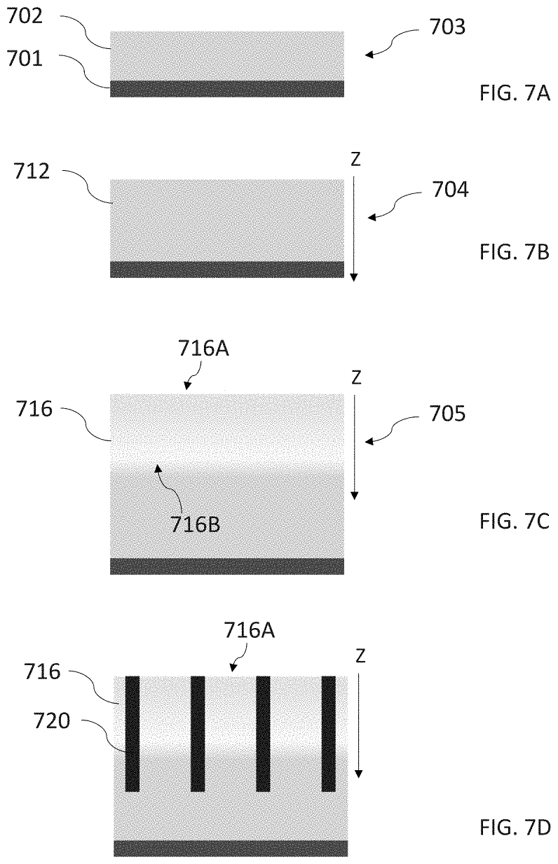

FIG. 6 illustrates doping profiles 601, 602 in the Z direction of a photodiode 300 according to the embodiment of FIG. 3, and doping profiles 603, 604 in the Z direction of a photodiode according to the variant of the photodiode of FIG. 3 where the P doped region is doped with a gradual dopant concentration in the Z direction (gradient). Profiles 601 and 603 are substantially similar: peaks 601a and 603a correspond to the P+-doped (ion implantation) region at the upper surface of the substrate, peaks 601b and 603b correspond to the second N-doped (ion implantation) region under the P+ regions, and portions 601c, 603c correspond to the first gradually N-doped (epitaxial) region (concentration decreasing in the Z direction between N4 and N3). Profiles 602 and 604 correspond to the P-doped (epitaxial) region of each photodiode, and are thus different. Doping profiles 602 and 604 respectively correspond to a substantially constant P dopant concentration (P1) and to a gradual P dopant concentration in the Z direction (increasing in the Z direction between P1 and P2).

For FIG. 6 and FIGS. 7A to 7F, dopant concentrations N3, N4, P1, P2 refer to FIG. 3 and to the associated description.

FIGS. 7A to 7F are cross-section views showing steps of a method of manufacturing a photodiode according to an embodiment.

FIG. 7A shows an initial substrate 703 (first substrate) comprising a heavily P-doped support 701 topped with a P-doped silicon layer 702.

FIG. 7B shows a substrate 704 obtained at the end of a step of epitaxial growth with a gas comprising silicon and a P-type dopant, for example, boron, to form a P-doped silicon epitaxial layer 712 (P-type region), for example, of a thickness of approximately 2 μm. The P dopant concentration of the epitaxial layer is, for example, equal to P1 and is substantially constant along the growth.

According to a variant, the P dopant concentration gradually decreases during the epitaxial growth. For example, at the beginning of the growth, the dopant concentration is equal to P2 and then gradually decreases to P1 at the end of the growth.

It should be noted that, according to an alternative method, the initial substrate (first substrate) may be this substrate 704 provided with the P-type epitaxial layer, constant or gradual.

FIG. 7C shows a substrate 705 obtained at the end of a step of epitaxial growth with a gas comprising silicon and an N-type dopant, for example, phosphorus or arsenic, the dopant concentration gradually increasing from the P-doped epitaxial layer 712, to form a gradually N-doped epitaxial silicon layer 716 (first N-type region), for example, having a 5 -μm thickness. At the beginning of the growth, the N dopant concentration of the epitaxial layer is for example equal to N3 and then gradually increases to N4 at the end of the growth.

FIG. 7D has a structure obtained at the end of a step of forming of insulating trenches 720, for example, by etching through openings of a hard mask deposited on the upper surface 716A of N-doped epitaxial layer 716 (hard mask not shown). The trenches may be insulated from the substrate and then, for example, filled with a conductive or semiconductor substrate, such as a metal or polysilicon to obtain insulating trenches (CDTI) similar to the insulating trenches 120 of FIGS. 2 and 3. The hard mask is then removed.

FIG. 7E shows a structure obtained at the end of a step of ion implantation from the upper surface 716A of N-doped epitaxial layer 716 to form, between trenches 720, heavily N-doped regions 714 (more heavily doped than epitaxial layer 716), and then a step of ion implantation at the upper surface of each heavily N-doped region 714, to form heavily P-doped regions 718.

The N dopant concentrations of implantation regions 714 are, for example, equal to a few 10¹⁷ at./cm³. The P dopant concentrations of implantation regions 718 are, for example, in the range from a few 10¹⁸ at./cm³ to a few 10¹⁹ at./cm³. The heights of implantation regions 714 may be in the order of one micrometer, for example, approximately 1.5 μm. The heights of implantation regions 718 may be of a few tens of nanometers, for example, approximately 50 nm.

FIG. 7F shows a structure 700 (photodiode) obtained at the end of the forming of an interconnection structure 730 on the upper surface of the structure of FIG. 7E (surface which comprises ion implantation regions 714, 718) and of a step of polishing on the lower surface of said structure (surface which comprises initial substrate 703). The interconnection structure typically comprises insulating layers having interconnection elements such as conductive vias, conductive tracks, and/or conductive pads arranged therein. The polishing step is adapted to removing support 701, all or part of layer 702, or even a small thickness of layer 712. It may be performed by turning over the structure of FIG. 7E, for example, after the forming of the interconnection structure.

A photodiode according to an embodiment may be comprised in an indirect TOF sensor pixel, in order for example to improve the demodulation contrast, or in a direct TOF sensor, in order for example to improve another parameter, such as the time resolution.

Various embodiments and variants have been described. Those skilled in the art will understand that certain features of these various embodiments and variants may be combined, and other variants will occur to those skilled in the art. In particular, those skilled in the art may adapt the epitaxial growth steps, for example, the nature of the gases and of the dopants, as well as the ion implantation steps.

Finally, the practical implementation of the described embodiments and variations is within the abilities of those skilled in the art based on the functional indications given hereabove.

1. A photodiode, comprising:
a semiconductor substrate having a first surface and a second surface;
wherein the semiconductor substrate includes a first N-type semiconductor region formed by epitaxial growth and a second N-type semiconductor region;
wherein the second N-type semiconductor region is more heavily-doped than the first N-type semiconductor region;
wherein said second N-type semiconductor region extends into the first N-type semiconductor region from the first surface of the semiconductor substrate down to a first depth in the first N-type semiconductor region; and
wherein a dopant concentration of the first N-type semiconductor region exhibits a concentration gradient that gradually increases between the second surface and the first surface of the semiconductor substrate.

2. The photodiode according to claim 1, wherein the semiconductor substrate further comprises a P-type semiconductor region between the first N-type semiconductor region and the second surface of the semiconductor substrate.

3. The photodiode according to claim 2, wherein a height of the P-type semiconductor region from the second surface is in a range from 0.5 μm to 3 μm.

4. The photodiode according to claim 2, wherein the P-type semiconductor region exhibits a concentration gradient that gradually decreases between the second surface and the first N-type semiconductor region.

5. The photodiode according to claim 2, wherein a dopant concentration of the P-type semiconductor region is substantially constant between the second surface and the first N-type semiconductor region.

6. The photodiode according to claim 1, further comprising a heavily P-doped semiconductor region on the second N-type semiconductor region at a level of the first surface of the semiconductor substrate.

7. The photodiode according to claim 6, wherein a dopant concentration of the heavily P-doped semiconductor region is in a range from a few 10¹⁸ at./cm³ to a few 10¹⁹ at./cm³.

8. The photodiode according to claim 6, wherein the heavily P-doped region is formed by ion implantation.

9. The photodiode according to claim 1, wherein a height of the first N-type semiconductor region is in a range from 4.5 μm to 10 μm.

10. The photodiode according to claim 1, wherein a depth of the second N-type semiconductor region from the first surface is in a range from 1 μm to 2 μm.

11. The photodiode according to claim 1, wherein the concentration gradient of the first N-type semiconductor region increases by a ratio in a range from 2 to 100.

12. The photodiode according to claim 1, wherein a dopant concentration of the second N-type semiconductor region is of a few 10¹⁷ at./cm³.

13. The photodiode according to claim 1, wherein the second N-type semiconductor region is formed by ion implantation.

14. The photodiode according to claim 1, wherein the semiconductor substrate is made of silicon.

15. The photodiode according to claim 1, further comprising insulating trenches extending across a height of the semiconductor substrate to insulate said photodiode.

16. The photodiode according to claim 15, wherein said insulating trenches are capacitive deep trench insulations.

17. The photodiode according to claim 1, wherein the concentration gradient of the first N-type semiconductor region ranges from a few 10¹⁴ at./cm³ to a few 10¹⁶ at./cm³.

18. An electronic device comprising at least one photodiode according to claim 1.

19. The electronic device according to claim 18, wherein said electronic device is a time-of-flight image sensor comprising a plurality of pixels wherein each pixel comprising said at least one photodiode.

20. A method of manufacturing, comprising:
providing a first semiconductor substrate;
forming, by epitaxial growth on the first semiconductor substrate, a first N-type semiconductor region;
wherein the first N-type semiconductor region exhibits a concentration gradient having a gradual increase in N-type dopant concentration so that the first N-type semiconductor region comprises a first surface most distant from the first semiconductor substrate that is more heavily N-type doped than a second surface closest to the first semiconductor substrate; and
forming a second N-type semiconductor region extending in to the first N-type semiconductor region from said first surface down to a first depth;
wherein the second N-type semiconductor region is more heavily doped than the first N-type semiconductor region.

21. The method according to claim 20, wherein the concentration gradient of the first N-type semiconductor region increases by a ratio in a range from 2 to 100.

22. The method according to claim 20, wherein a dopant concentration of the second N-type semiconductor region is of a few 10¹⁷ at./cm³.

23. The method according to claim 20, wherein the forming the second N-type semiconductor region comprises performing an ion implantation.

24. The method according to claim 20, wherein the first semiconductor substrate comprises a P-type semiconductor region, and wherein forming the first N-type semiconductor region by epitaxial growth is performed from said P-type semiconductor region.

25. The method according to claim 20, further comprising, prior to forming of the first N-type semiconductor region, forming a P-type semiconductor region by epitaxial growth from the first semiconductor substrate; and wherein forming the first N-type semiconductor region by epitaxial growth is performed from said P-type semiconductor region.

26. The method according to claim 20, wherein a dopant concentration of the P-type semiconductor region is substantially constant.

27. The method according to claim 20, wherein the P-type semiconductor region exhibits a concentration gradient that gradually decreases between the first semiconductor substrate and the first N-type semiconductor region.

28. The method according to claim 20, further comprising forming a heavily P-doped semiconductor region on the second N-type semiconductor region.

29. The method according to claim 28, wherein a dopant concentration of the heavily P-doped semiconductor region is in a range from a few 10¹⁸ at./cm³ to a few 10¹⁹ at./cm³.

30. The method according to claim 28, wherein forming the heavily P-doped semiconductor region comprises performing an ion implantation.

31. The method according to claim 20, wherein the first semiconductor substrate is made of silicon.

32. The method according to claim 20, further comprising forming insulating trenches extending through at least the first N-type semiconductor region.

33. The method according to claim 32, further comprising removing the first semiconductor substrate to reach said insulating trenches.
